(19) United States
(12) Patent Application Publication
(10) Pub. No.: US 2026/0170212 A1
(43) Pub. Date: Jun. 18, 2026

(54) METHOD FOR EVALUATING REAL MEASUREMENT RESULTS, SYSTEM ARRANGED FOR PERFORMING SUCH METHOD, AND CORRESPONDING MEASUREMENT DEVICE

(71) Applicant: Rohde & Schwarz GmbH & Co. KG, Munich (DE)

(72) Inventors: Julius SEEGER, Prien am Chiemsee (DE); Philipp KURPIERS, Moosburg (DE)

(73) Assignee: Rohde & Schwarz GmbH & Co. KG, Munich (DE)

(21) Appl. No.: 19/329,962

(22) Filed: Sep. 16, 2025

(30) Foreign Application Priority Data
Dec. 13, 2024 (DE) 10 2024 137 583.3

(51) Int. Cl. G06F 30/3308

(52) U.S. Cl. CPC G06F 30/3308

(57) ABSTRACT

A method for evaluating real measurement results is provided. Said method comprises the steps of simulating a device under test, DUT, based on a certain set of measurement parameters to obtain simulated DUT results, simulating a measurement system based on the certain set of measurement parameters and/or a further set of measurement parameters to obtain simulated measurement system results, simulating a measurement, wherein the DUT and the measurement system interact, to obtain simulated measurement results, performing a real measurement, wherein the DUT and the measurement system interact, to obtain real measurement results, and comparing the real measurement results to at least one of the simulated DUT results, the simulated measurement system results, the simulated measurement results, or any combination thereof, to obtain evaluation results.

### FIELD OF THE INVENTION

The invention relates to a method for evaluating real measurement results, a system arranged for performing such a method, and a corresponding measurement device.

### BACKGROUND

In times of measurements becoming more and more complex, there is growing need for a method for evaluating real measurement results, a system arranged for performing such a method, and a corresponding measurement device.

Disadvantageously, in the context of performing such complex measurements with the aid of conventional test setups, exemplarily comprising a measurement system and a device under test being in connection therewith, there is typically low confidence for judgment of the performance of the DUT for such high-end or complex measurements, respectively, which may, for instance, lead to the necessity of time-consuming verification with another test setup.

### PROBLEM AND SOLUTION

Accordingly, it is an object of the invention to provide a method for evaluating real measurement results, a system arranged for performing such a method, and a corresponding measurement device in order to evaluate corresponding measurement results in a particularly efficient and reliable manner.

The object is solved with regard to the method for evaluating real measurement results by the features of the first independent patent claim. The object is solved with respect to the system arranged for performing such a method by the features of the second independent patent claim. The object is solved with regard to the corresponding measurement device by the features of the third independent patent claim. The dependent patent claims contain advantageous further embodiments.

### DETAILED DESCRIPTION OF THE INVENTION

According to a first aspect of the invention, a method for evaluating real measurement results is provided. Said method comprises the steps of simulating a device under test, DUT, based on a certain set of measurement parameters to obtain simulated DUT results, simulating a measurement system based on the certain set of measurement parameters and/or a further set of measurement parameters to obtain simulated measurement system results, simulating a measurement, wherein the DUT and the measurement system interact, to obtain simulated measurement results, performing a real measurement, wherein the DUT and the measurement system interact, to obtain real measurement results, and comparing the real measurement results to at least one of the simulated DUT results, the simulated measurement system results, the simulated measurement results, or any combination thereof, to obtain evaluation results.

Advantageously, corresponding measurement results can be evaluated in a particularly efficient and reliable manner. Further advantageously, a time-consuming verification with the aid of another test setup can be avoided.

According to an implementation form of the first aspect of the invention, the method further comprises the step of, preferably in the context of obtaining the evaluation results, comparing the simulated DUT results to the simulated measurement results to obtain first comparison results.

Advantageously, for instance, the evaluation results can comprise the first comparison results.

According to an implementation form of the first aspect of the invention, the method further comprises the step of, preferably in the context of obtaining the evaluation results, comparing the simulated measurement system results to the simulated measurement results to obtain second comparison results.

Advantageously, for example, the evaluation results can comprise the second comparison results.

According to an implementation form of the first aspect of the invention, the method further comprises the step of, preferably in the context of obtaining the evaluation results, extracting and/or categorizing correlations between the DUT and the measurement system based on the first comparison results and/or the second comparison results.

With respect to the term “correlations between the DUT and the measurement system”, it is noted that said term may especially be understood as correlations between variables and/or data related to the DUT and variables and/or data related to the measurement system. For instance, correlations may exist between the corresponding simulation and/or measurement and/or comparison results.

Advantageously, for instance, an impact of the measurement system can be determined in a particularly efficient manner.

According to an implementation form of the first aspect of the invention, the method further comprises the step of, preferably in the context of obtaining the evaluation results, determining a model for separating influences of the DUT and/or of the measurement system, especially on the simulated measurement results and/or the real measurement results, and/or for obtaining measurement uncertainties, especially with respect to the simulated measurement results and/or the real measurement results, based on the correspondingly extracted and/or categorized correlations.

Advantageously, for example, based on the model, a user can be prompted to change the corresponding measurement setup if the measurement system predominates. Further advantageously, the evaluation results can comprise said model.

With respect to the term “if the measurement system predominates”, it is noted that said term may especially be understood as “if the characteristics of the measurement system are decisive or substantially decisive for the corresponding results”.

According to an implementation form of the first aspect of the invention, the method further comprises the step of, preferably in the context of obtaining the evaluation results, separating the influences of the DUT and/or of the measurement system, especially on the simulated measurement results and/or the real measurement results, based on the correspondingly determined model, and/or, preferably in the context of obtaining the evaluation results, obtaining the measurement uncertainties, especially with respect to the simulated measurement results and/or the real measurement results, based on the correspondingly determined model.

Advantageously, for instance, not only time efficient verification of the DUT but also separating influences of the used measurement system on the measurement results is possible within the corresponding measurement setup itself.

According to an implementation form of the first aspect of the invention, the method further comprises the step of, preferably in the context of obtaining the evaluation results, comparing the real measurement results to the simulated measurement results to obtain third comparison results.

Advantageously, for example, the evaluation results can comprise the third comparison results.

According to an implementation form of the first aspect of the invention, the method further comprises the step of, preferably in the context of obtaining the evaluation results, separating influences of the DUT and/or of the measurement system, especially on the simulated measurement results and/or the real measurement results, based on the third comparison results, and/or, preferably in the context of obtaining the evaluation results, obtaining measurement uncertainties, especially with respect to the simulated measurement results and/or the real measurement results, based on the third comparison results.

Advantageously, for instance, efficiency can further be increased.

According to an implementation form of the first aspect of the invention, the method further comprises the steps of, preferably in the context of obtaining the evaluation results, performing a reference measurement with respect to the measurement system to obtain reference measurement results, and, preferably in the context of obtaining the evaluation results, comparing the reference measurement results to the simulated measurement system results to obtain fourth comparison results.

Advantageously, for example, the evaluation results can comprise the fourth comparison results.

According to an implementation form of the first aspect of the invention, the method further comprises the step of, preferably in the context of obtaining the evaluation results, validating the simulated measurement system results based on the fourth comparison results to obtain validation results.

Advantageously, for instance, the simulation of the measurement system can efficiently be improved. Further advantageously, the evaluation results can comprise the validation results.

According to an implementation form of the first aspect of the invention, the method further comprises the step of, preferably in the context of obtaining the evaluation results, separating influences of the DUT and/or of the measurement system, especially on the simulated measurement results and/or the real measurement results, based on the validation results, and/or, preferably in the context of obtaining the evaluation results, obtaining measurement uncertainties, especially with respect to the simulated measurement results and/or the real measurement results, based on the validation results.

Advantageously, for example, efficiency can further be increased, which can analogously apply for the following implementation forms.

According to an implementation form of the first aspect of the invention, the measurement uncertainties comprise or are an error and/or an error vector magnitude, preferably a bar representing an error and/or error vector magnitude, more preferably an error and/or an error vector magnitude being superimposed with respect to the real measurement results and/or the simulated measurement results, most preferably a bar representing an error and/or error vector magnitude being superimposed with respect to the real measurement results and/or the simulated measurement results.

According to an implementation form of the first aspect of the invention, the method further comprises the step of outputting and/or displaying the evaluation results, especially to a user, and/or outputting and/or displaying at least one of the real measurement results, the simulated DUT results, the simulated measurement system results, the simulated measurement results, or any combination thereof, especially to a user.

According to a second aspect of the invention, a system arranged for performing a method according to the first aspect of the invention or any of its implementation forms, respectively, is provided.

Advantageously, corresponding measurement results can be evaluated in a particularly efficient and reliable manner. Further advantageously, a time-consuming verification with the aid of another test setup can be avoided.

According to a third aspect of the invention, a measurement device is provided, said measurement device having stored thereon and/or being arranged for being supplied with simulation data for at least one of a device under test, DUT, a measurement system, the measurement device, the DUT interacting with the measurement system, the DUT interacting with the measurement device, or any combination thereof, and for taking said simulation data for comparing said simulation data with real measurement data obtained by performing a real measurement, wherein the DUT and the measurement system or the DUT and the measurement device interact, to obtain evaluation results.

Advantageously, corresponding measurement results can be evaluated in a particularly efficient and reliable manner. Further advantageously, a time-consuming verification with the aid of another test setup can be avoided.

It is noted that all implementation forms of the first aspect of the invention can apply to the third aspect of the invention in an analogous manner.

### DESCRIPTION OF PREFERRED EMBODIMENTS

A detailed exemplary description of some embodiments of the invention is given below with reference to the figures according to the drawings. In this context:

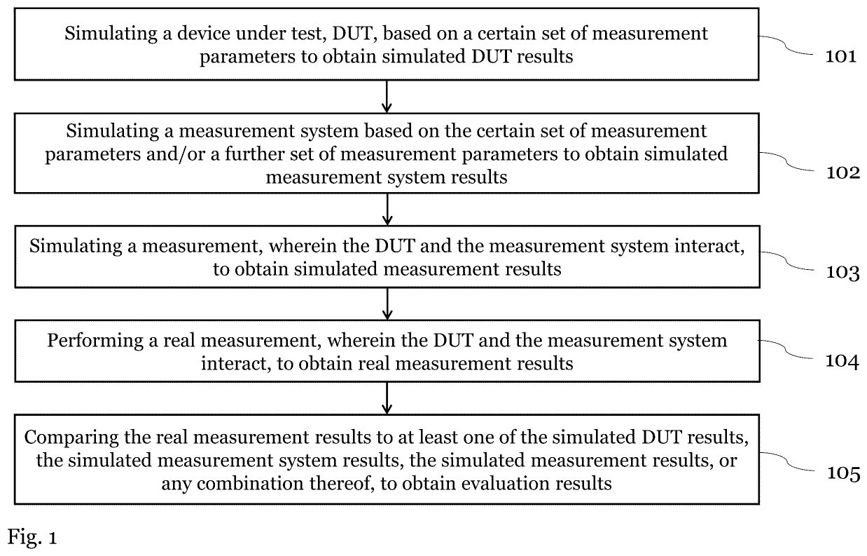

FIG. 1 shows a flow chart of an exemplary embodiment of a method for evaluating real measurement results;

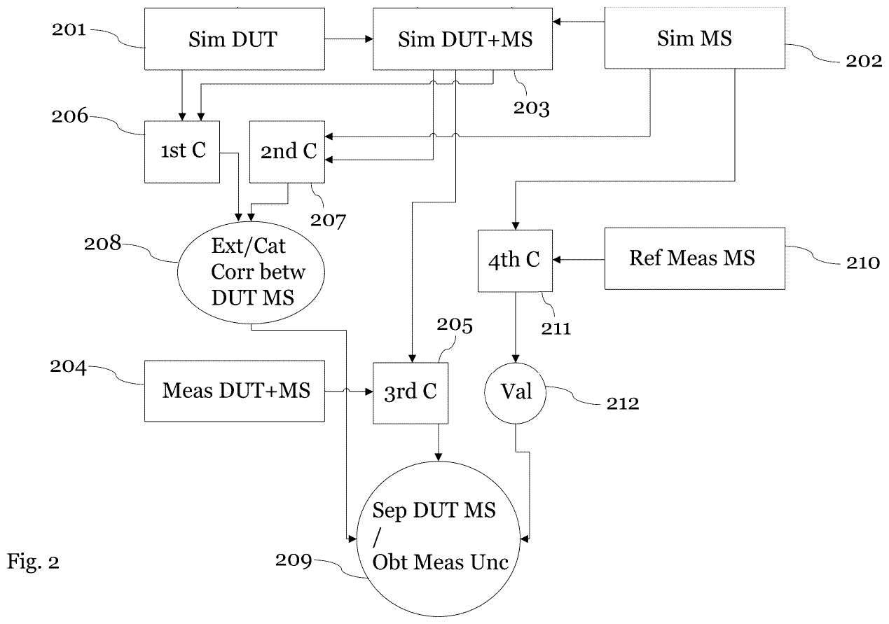

FIG. 2 shows a flow chart of a further exemplary embodiment of a method for evaluating real measurement results;

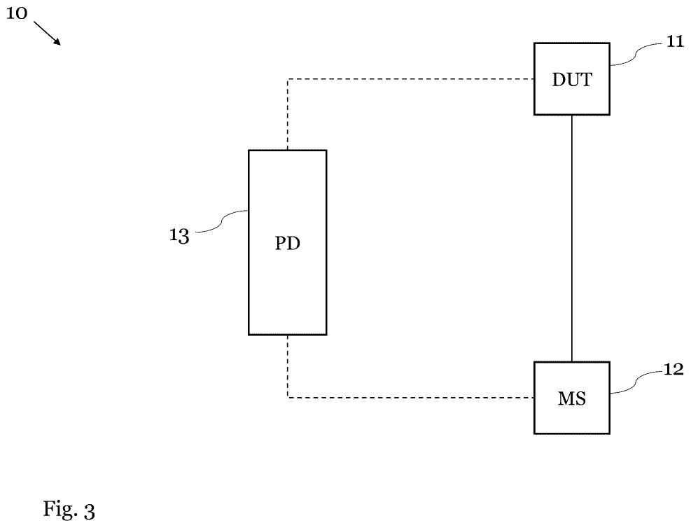

FIG. 3 shows an exemplary embodiment of a system arranged for performing a method according to FIG. 1 or FIG. 2, respectively;

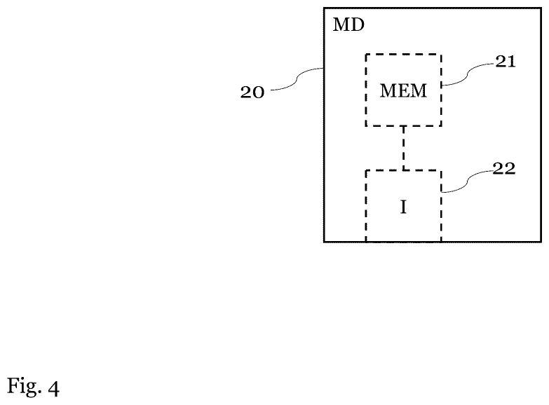

FIG. 4 shows an exemplary embodiment of a measurement device; and

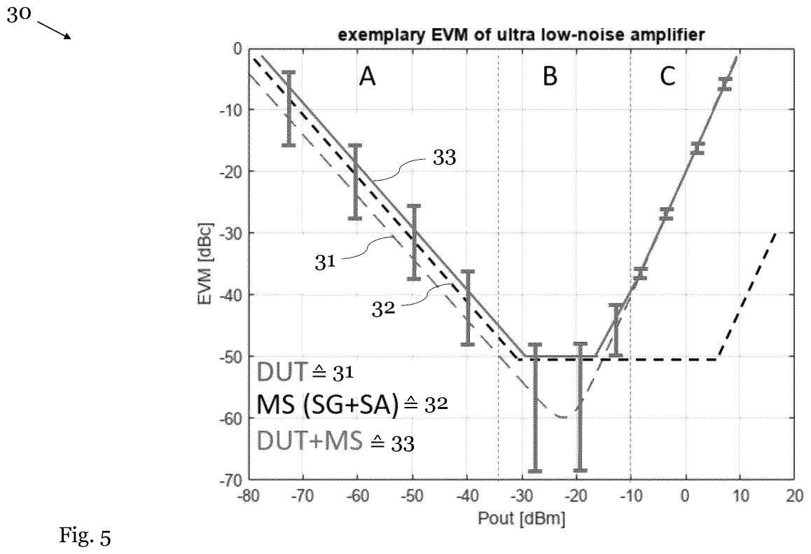

FIG. 5 shows an exemplary error vector magnitude diagram in the context of illustrating separation of influences and obtaining measurement uncertainties.

FIG. 1 illustrates a flow chart of an exemplary embodiment of a method for evaluating real measurement results.

In accordance with said FIG. 1, a first step 101 comprises simulating a device under test, DUT, based on a certain set of measurement parameters to obtain simulated DUT results. It is noted that the method may comprise a step, especially before said step 101, comprising providing a DUT model. Said DUT model can, for instance, provide and/or comprise said certain set of measurement parameters.

Accordingly, step 101 can especially be understood as a step of simulating a device under test, DUT, based on a DUT model to obtain simulated DUT results.

As it can further be seen from FIG. 1, a second step 102 comprises simulating a measurement system based on the certain set of measurement parameters and/or a further set of measurement parameters to obtain simulated measurement system results. It is noted that the method may comprise a step, especially at least before said step 102, comprising providing a measurement system model. Said measurement system model can, for instance, provide and/or comprise said certain set of measurement parameters and/or said further set of measurement parameters.

Accordingly, step 102 can especially be understood as a step of simulating a measurement system based on a measurement system model to obtain simulated measurement system results.

Furthermore, a third step 103 comprises simulating a measurement, wherein the DUT and the measurement system interact, to obtain simulated measurement results.

Accordingly, step 103 can especially be understood as a step of simulating a measurement based on the DUT model and the measurement system model to obtain simulated measurement results.

Moreover, a fourth step 104 comprises performing a real measurement, wherein the DUT and the measurement system interact, to obtain real measurement results.

A fifth step 105 comprises comparing the real measurement results to at least one of the simulated DUT results, the simulated measurement system results, the simulated measurement results, or any combination thereof, to obtain evaluation results.

It is noted that it might be particularly advantageous if the method further comprises the step of outputting and/or displaying at least the evaluation results, especially to a user.

Now, with respect to FIG. 2, a flow chart of a further exemplary embodiment of a method for evaluating real measurement results is depicted.

As indicated above, a DUT model may be provided for a simulation of a DUT according to step 201. It is noted that said step 201 may especially be understood as being analogous to step 101 of FIG. 1. It is further noted that the simulation of the DUT leads to simulated DUT results.

Furthermore, for a simulation of a measurement system according to step 202, a measurement system model may be provided. It is noted that said step 202 may especially be understood as being analogous to step 102 according to FIG. 1. It is further noted that the simulation of the measurement system leads to simulated measurement system results.

Moreover, step 203 comprises a simulation of the DUT and the measurement system or of the DUT interacting with the measurement system, respectively, exemplarily based on the DUT model and the measurement system model. It is noted that said step 203 may especially be understood as being analogous to step 103 of FIG. 1. It is further noted that the simulation of the DUT and the measurement system or of the DUT interacting with the measurement system, respectively, leads to simulated measurement results.

As it can further be seen from FIG. 2, step 204 comprises a measurement, especially a real measurement, of the DUT and the measurement system or of the DUT interacting with the measurement system, respectively. It is noted that said step 204 may especially be understood as being analogous to step 104 of FIG. 1. It is further noted that the measurement, especially the real measurement, of the DUT and the measurement system or of the DUT interacting with the measurement system, respectively, leads to real measurement results.

Especially by analogy with step 105 according to FIG. 1, it might be particularly advantageous if the method comprises the step of comparing the real measurement results to at least one of the simulated DUT results, the simulated measurement system results, the simulated measurement results, or any combination thereof, to obtain evaluation results.

In advance, with special respect to the exemplary case according to FIG. 2, it is noted that step 205 of said FIG. 2 is similar to step 105 of FIG. 1. Nevertheless, said step 205 will be explained later in the following.

As it can further be seen from FIG. 2, a step 206 comprises, preferably in the context of obtaining the evaluation results, comparing the simulated DUT results to the simulated measurement results to obtain first comparison results. The evaluation results can comprise said first comparison results.

Furthermore, a step 207 comprises, preferably in the context of obtaining the evaluation results, comparing the simulated measurement system results to the simulated measurement results to obtain second comparison results. The evaluation results can comprise said second comparison results.

Moreover, a step 208 comprises, preferably in the context of obtaining the evaluation results, extracting and/or categorizing correlations between the DUT and the measurement system based on the first comparison results and/or the second comparison results. The evaluation results can comprise said correlations.

Said step 208 or an additional step can comprise, preferably in the context of obtaining the evaluation results, determining a model for separating influences of the DUT and/or of the measurement system, especially on the simulated measurement results and/or the real measurement results, and/or for obtaining measurement uncertainties, especially with respect to the simulated measurement results and/or the real measurement results, based on the correspondingly extracted and/or categorized correlations. The evaluation results can comprise said model.

Furthermore, a step 209 comprises, preferably in the context of obtaining the evaluation results, separating the influences of the DUT and/or of the measurement system, especially on the simulated measurement results and/or the real measurement results, based on the correspondingly determined model. Additionally or alternatively, said step 209 can comprise, preferably in the context of obtaining the evaluation results, obtaining the measurement uncertainties, especially with respect to the simulated measurement results and/or the real measurement results, based on the correspondingly determined model. The evaluation results can comprise said influences and/or said measurement uncertainties.

As announced above, the step 205 comprises, preferably in the context of obtaining the evaluation results, comparing the real measurement results to the simulated measurement results to obtain third comparison results. The evaluation results can comprise said third comparison results.

Moreover, the step 209 can comprise, preferably in the context of obtaining the evaluation results, separating influences of the DUT and/or of the measurement system, especially on the simulated measurement results and/or the real measurement results, based on the third comparison results. Additionally or alternatively, the step 209 can comprise, preferably in the context of obtaining the evaluation results, obtaining measurement uncertainties, especially with respect to the simulated measurement results and/or the real measurement results, based on the third comparison results. The evaluation results can comprise said influences and/or said measurement uncertainties.

As it can further be seen from FIG. 2, a step 210 comprises, preferably in the context of obtaining the evaluation results, performing a reference measurement with respect to the measurement system to obtain reference measurement results. The evaluation results can comprise said reference measurement results.

Furthermore, a step 211 comprises, preferably in the context of obtaining the evaluation results, comparing the reference measurement results to the simulated measurement system results to obtain fourth comparison results. The evaluation results can comprise said fourth comparison results.

Advantageously, the reference measurement or the reference measurement results, respectively, can be used for improving the simulation of the measurement system.

Moreover, a step 212 comprises, preferably in the context of obtaining the evaluation results, validating the simulated measurement system results based on the fourth comparison results to obtain validation results. The evaluation results can comprise said validation results.

Especially in this context, the step 209 can comprise, preferably in the context of obtaining the evaluation results, separating influences of the DUT and/or of the measurement system, especially on the simulated measurement results and/or the real measurement results, based on the validation results. Additionally or alternatively, the step 209 can comprise, preferably in the context of obtaining the evaluation results, obtaining measurement uncertainties, especially with respect to the simulated measurement results and/or the real measurement results, based on the validation results. The evaluation results can comprise said influences and/or said measurement uncertainties.

With respect to the measurement uncertainties, exemplarily obtained by step 209, it is noted that it might be particularly advantageous if the measurement uncertainties comprise or are an error and/or an error vector magnitude, preferably a bar representing an error and/or error vector magnitude, more preferably an error and/or an error vector magnitude being superimposed with respect to the real measurement results and/or the simulated measurement results, most preferably a bar representing an error and/or error vector magnitude being superimposed with respect to the real measurement results and/or the simulated measurement results.

It is further noted that it might be particularly advantageous if the method comprises the step of outputting and/or displaying the evaluation results, especially to a user. Additionally or alternatively, the method can comprise the step of outputting and/or displaying at least one of the real measurement results, the simulated DUT results, the simulated measurement system results, the simulated measurement results, or any combination thereof, especially to a user or the user, respectively.

It might be particularly advantageous if the method further comprises the step of informing a user or the user, respectively, based on the evaluation results, if the real measurement results are correct or at least correct with a certain probability.

The method can further comprise the step of informing a user or the user, respectively, based on the evaluation results, if the measurement system has a minor impact to the real measurement results.

The method can further comprise the step of prompting a user or the user, respectively, based on the evaluation results, to change the corresponding measurement setup or the measurement system if the measurement system or the influence thereof, respectively, predominates.

The method can further comprise the step of informing a user or the user, respectively, based on the evaluation results, to use the real measurement results if the DUT or the influence thereof, respectively, predominates.

By analogy with such a formulation regarding the measurement system, the term “if the DUT predominates” may especially be understood as “if the characteristics of the DUT are decisive or substantially decisive for the corresponding results”.

Advantageously, with respect to the method, it is noted that a systematic consideration of the influences of the measurement system on the real measurement results can give the user of the measurement system more reliable measurement results of the DUT with additionally determined measurement uncertainty.

With respect to the first comparison results and the second comparison results, it is noted that each of said comparison results may especially be understood as a measure of similarity of the corresponding two simulated results. Said similarity can especially comprise information about the corresponding correlations between the respective two simulation inputs.

Especially in this context, the following comparative cases or classification, respectively, may exemplarily be made:

For the case that the simulated measurement results are equal or substantially equal to the simulated measurement system results, the measurement system is limiting and therefore real separation may not be possible in all cases. From the good modeling and the simulation derived therefrom, however, there is the possibility of assigning meaningful error bars and their respective origin (measurement system or DUT). The error bar has a great value for the user, and the cause or origin can be used for evaluating the results. From a good model, a prediction of parameter variations can be generated in order to improve the measurements even with the limitations of the present measurement system.

With respect to the above-mentioned term “substantially equal”, it is noted that said term may especially be understood as a corresponding deviation of not more than 20 per cent, preferably not more than 15 per cent, more preferably not more than 10 per cent, most preferably not more than 5 per cent. This can analogously apply in the following.

For the case that the simulated measurement results are equal or substantially equal to the simulated DUT results, the influences of the DUT and the measurement system can be separated on the measurement result. Accordingly, an error bar on the DUT can correspondingly be reduced to the error bar on the “pure” measurement result, which advantageously enables the user to increase the measurement accuracy without requiring expensive, additional solutions.

For the case that the simulated measurement results are unequal to the simulated DUT results and/or the simulated measurement results are unequal to the simulated measurement system results, the measurement results may not be influenced so strongly by the DUT alone or by the measurement system alone that the influences of the respective other part might be irrelevant. Therefore, limitations of the measurement system or of the DUT, respectively, can be determined on the one hand, and on the other hand the error bars and different influences can be separated.

With respect to the third comparison results, it is noted that the results of the real measurement (the DUT interacting with measurement system) can be combined with the simulation of the measurement (the DUT interacting with measurement system) in order to determine the optimal parameters for the description of the DUT. Such optimal parameters can in particular comprise parameters with the highest probability such as maximum-likelihood estimators (MLEs) or parameters which minimize an error metric such as least-square estimators (LSQEs).

Again, especially with respect to the first comparison results or the second comparison results, respectively, the respective simulation-simulation comparisons can especially be used for the classification for determining the deviations and/or the corresponding separation. In this context, various methods can be used, especially depending on the corresponding classification, such as: LSQE, any regression models as e.g. median regression, Bayesian estimates, MLE, Monte-Carlo simulations, or any combination thereof.

Accordingly, it might be particularly advantageous if the method comprises the step of separating the influences of the DUT and/or of the measurement system, especially on the simulated measurement results and/or the real measurement results, preferably based on the correspondingly determined model and/or the third comparison results and/or the validation results, with the aid of at least one of LSQE, any regression models as e.g. median regression, Bayesian estimates, MLE, Monte-Carlo simulations, or any combination thereof.

With respect to the fourth comparison results, it is noted that the corresponding reference measurements can be used to check the modeling and simulation of the measurement system.

As an example, in the case of a vector network analyzer, VNA, or the measurement system comprises or is such a VNA, respectively, such a reference measurement can comprise or be a corresponding calibration or user calibration or OSM calibration, respectively. As another example, the determination of the corresponding compression point of the VNA may be seen as an example for a reference measurement.

Furthermore, especially in the context of the above-mentioned error vector magnitude, the reference measurement can comprise or be the determination of the error vector magnitude of the measurement system for certain specified operating parameters such as measuring bandwidth, frequency, level, or any combination thereof.

A reference measurement and the comparison with the simulation of this reference measurement offers various advantages.

For instance, even if the comparison measurement regarding the DUT interacting with the measurement system coincides with the simulation regarding the DUT interacting with the measurement system, a reference measurement and comparison with the simulation of the measurement system can be useful in order to exclude that two “errors” of the DUT and the measurement system are mutually cancelled in the specific case. In this case, the measurement result may still be true, but the separation and determination of the error bar that might be in focus here would be wrong.

Further exemplarily, if the comparison of the reference measurement with the simulation of the DUT gives deviations, it might be particularly advantageous to adapt the modeling of the DUT or the DUT model, respectively.

Moreover, two exemplary cases might be distinguished if the comparison of measurement regarding the DUT interacting with the measurement system does not match the simulation regarding the DUT interacting with the measurement system.

For the case that the reference measurement of the measurement system agrees or substantially agrees with the simulation of the measurement system, it might be particularly advantageous to revise the DUT model.

For the case that the reference measurement of the measurement system is not consistent with the simulation of the measurement system, it might be particularly advantageous to adapt the measurement system model.

It is noted that it might be particularly advantageous if the method comprises the step of checking the corresponding plausibility of the measurement system model and the simulation of the measurement system against each other with the aid of a reference measurement or the reference measurement, respectively.

In this context, it is further noted that it might be particularly advantageous if the method comprises the step of revising the measurement system model if the corresponding plausibility check has revealed deviations.

Now, with respect to FIG. 3, an exemplary embodiment of a system 10 arranged for performing a method according to FIG. 1 or FIG. 2, respectively, is illustrated.

Said system 10 comprises a DUT 11, a measurement system 12, and a processing device 13. The processing device 13 can be configured to perform the respective steps of the method according to FIG. 1 or of the method according to FIG. 2, respectively.

For instance, the processing device 13 can be supplied with the DUT model and/or the measurement system model. Further exemplarily, the processing device 13 can have stored the DUT model and/or the measurement system model. As a further example, the processing device 13 can be configured to retrieve the DUT model from the DUT 11, and/or to retrieve the measurement system model from the measurement system 12.

With respect to the measurement system 12, it is noted that said measurement system 12 can comprise or be a measurement device, such as a vector network analyzer, or a combination of measurement devices, such as a signal generator and a signal analyzer.

Furthermore, FIG. 4 depicts an exemplary embodiment of a measurement device 20 having stored thereon, exemplarily with the aid of a memory 21, and/or being arranged for being supplied, exemplarily via an interface 22, with simulation data for at least one of a device under test, DUT, such as the DUT 11 according to FIG. 3, a measurement system, such as the measurement system 12 according to FIG. 3, the measurement device, the DUT interacting with the measurement system, the DUT interacting with the measurement device, or any combination thereof, and for taking said simulation data for comparing said simulation data with real measurement data obtained by performing a real measurement, wherein the DUT and the measurement system or the DUT and the measurement device interact, to obtain evaluation results.

For instance, the measurement device 20 can be supplied with the DUT model and/or the measurement system model and/or a measurement device model with respect to the measurement device 20, exemplarily via the interface 22 of the measurement device 20. Further exemplarily, the measurement device 20, exemplarily with the aid of the memory 21 of the measurement device 20, can have stored the DUT model and/or the measurement system model and/or the measurement device model. As a further example, the measurement device 20 can be configured to retrieve the DUT model from the DUT, and/or to retrieve the measurement system model from the measurement system, exemplarily with the aid of the interface 22 of the measurement device 20. The respective model can comprise the corresponding simulation data.

Finally, FIG. 5 shows an exemplary error vector magnitude diagram 30 in the context of illustrating separation of influences and obtaining measurement uncertainties as described above.

Said diagram 30 exemplarily depicts the error vector magnitude of an ultra-low-noise amplifier. In this context, a first curve equipped with reference sign 31 relates to the corresponding DUT, a second curve equipped with reference sign 32 relates to the corresponding measurement system, exemplarily a combination of a signal generator and a signal analyzer, and a third curve equipped with reference sign 33 relates to the DUT interacting with the measurement system. Additionally, the diagram 30 is exemplarily divided into three different regions, namely A, B and C.

As it can be seen from FIG. 5, in region A, the noise figure of the measurement system predominantly limits the error vector magnitude (EVM). In region B, the phase noise of the measurement system limits the EVM completely. In region C, the non-linearity of the DUT limits the EVM.

As it can further be seen from said FIG. 5, especially in regions A and B, the corresponding measurement uncertainties can be shown, whereas especially in region C, the influences of the DUT and the measurement system can be separated.

Especially in the light of FIG. 5, it is noted that an exemplary use case for the method according to FIG. 1 or FIG. 2, respectively, the system 10 according to FIG. 3, and the measurement device 20 according to FIG. 4 can be a measurement with respect to an ultra-low-noise amplifier with the aid of a combination of a signal generator and a signal analyzer.

It is further noted that a further exemplary use case for the method according to FIG. 1 or FIG. 2, respectively, the system 10 according to FIG. 3, and the measurement device 20 according to FIG. 4 can be a compression point measurement with a vector network analyzer. Another exemplary use case can be a filter measurement with a vector network analyzer. Yet another exemplary use case can be a measurement of phase noise, especially additive phase noise.

The invention is not limited to the embodiments discussed above. All features described in the description or claimed in the patent claims or drawn in the drawing can be combined with each other as desired within the scope of the present invention.

1. A method for evaluating real measurement results, comprising the steps of:
simulating a device under test, DUT, based on a certain set of measurement parameters to obtain simulated DUT results,
simulating a measurement system based on the certain set of measurement parameters and/or a further set of measurement parameters to obtain simulated measurement system results,
simulating a measurement, wherein the DUT and the measurement system interact, to obtain simulated measurement results,
performing a real measurement, wherein the DUT and the measurement system interact, to obtain real measurement results, and
comparing the real measurement results to at least one of the simulated DUT results, the simulated measurement system results, the simulated measurement results, or any combination thereof, to obtain evaluation results.

2. The method according to claim 1, further comprising the step of:
preferably in the context of obtaining the evaluation results, comparing the simulated DUT results to the simulated measurement results to obtain first comparison results.

3. The method according to claim 1, further comprising the step of:
preferably in the context of obtaining the evaluation results, comparing the simulated measurement system results to the simulated measurement results to obtain second comparison results.

4. The method according to claim 2, further comprising the step of:
preferably in the context of obtaining the evaluation results, extracting and/or categorizing correlations between the DUT and the measurement system based on the first comparison results and/or the second comparison results.

5. The method according to claim 4, further comprising the step of:
preferably in the context of obtaining the evaluation results, determining a model for separating influences of the DUT and/or of the measurement system, especially on the simulated measurement results and/or the real measurement results, and/or for obtaining measurement uncertainties, especially with respect to the simulated measurement results and/or the real measurement results, based on the correspondingly extracted and/or categorized correlations.

6. The method according to claim 5, further comprising the step of:
preferably in the context of obtaining the evaluation results, separating the influences of the DUT and/or of the measurement system, especially on the simulated measurement results and/or the real measurement results, based on the correspondingly determined model, and/or
preferably in the context of obtaining the evaluation results, obtaining the measurement uncertainties, especially with respect to the simulated measurement results and/or the real measurement results, based on the correspondingly determined model.

7. The method according to claim 1, further comprising the step of:
preferably in the context of obtaining the evaluation results, comparing the real measurement results to the simulated measurement results to obtain third comparison results.

8. The method according to claim 7, further comprising the step of:
preferably in the context of obtaining the evaluation results, separating influences of the DUT and/or of the measurement system, especially on the simulated measurement results and/or the real measurement results, based on the third comparison results, and/or
preferably in the context of obtaining the evaluation results, obtaining measurement uncertainties, especially with respect to the simulated measurement results and/or the real measurement results, based on the third comparison results.

9. The method according to claim 1, further comprising the steps of:
preferably in the context of obtaining the evaluation results, performing a reference measurement with respect to the measurement system to obtain reference measurement results, and
preferably in the context of obtaining the evaluation results, comparing the reference measurement results to the simulated measurement system results to obtain fourth comparison results.

10. The method according to claim 9, further comprising the step of:
preferably in the context of obtaining the evaluation results, validating the simulated measurement system results based on the fourth comparison results to obtain validation results.

11. The method according to claim 10, further comprising the step of:
preferably in the context of obtaining the evaluation results, separating influences of the DUT and/or of the measurement system, especially on the simulated measurement results and/or the real measurement results, based on the validation results, and/or
preferably in the context of obtaining the evaluation results, obtaining measurement uncertainties, especially with respect to the simulated measurement results and/or the real measurement results, based on the validation results.

12. The method according to claim 5, wherein the measurement uncertainties comprise or are an error and/or an error vector magnitude, preferably a bar representing an error and/or error vector magnitude, more preferably an error and/or an error vector magnitude being superimposed with respect to the real measurement results and/or the simulated measurement results, most preferably a bar representing an error and/or error vector magnitude being superimposed with respect to the real measurement results and/or the simulated measurement results.

13. The method according to claim 1, further comprising the step of:
outputting and/or displaying the evaluation results, especially to a user, and/or
outputting and/or displaying at least one of the real measurement results, the simulated DUT results, the simulated measurement system results, the simulated measurement results, or any combination thereof, especially to a user.

14. System arranged for performing a method according to claim 1.

15. Measurement device having stored thereon and/or being arranged for being supplied with simulation data for at least one of a device under test, DUT, a measurement system, the measurement device, the DUT interacting with the measurement system, the DUT interacting with the measurement device, or any combination thereof, and for taking said simulation data for comparing said simulation data with real measurement data obtained by performing a real measurement, wherein the DUT and the measurement system or the DUT and the measurement device interact, to obtain evaluation results.
